(19) United States
(12) Patent Application Publication
(10) Pub. No.: US 2016/0017495 A1
(43) Pub. Date: Jan. 21, 2016

(54) PLASMA-ENHANCED AND RADICAL-BASED CVD OF POROUS CARBON-DOPED OXIDE FILMS ASSISTED BY RADICAL CURING

(71) Applicant: Applied Materials, Inc., Santa Clara, CA (US)

(72) Inventors: Yihong CHEN, San Jose, CA (US); Kelvin CHAN, San Ramon, CA (US); Martin Jay SEAMONS, San Jose, CA (US); Shaunak MUKHERJEE, Santa Clara, CA (US); Abhijit Basu MALLICK, Fremont, CA (US); Jianhua ZHOU, Campbell, CA (US); Kang Sub YIM, Palo Alto, CA (US)

(21) Appl. No.: 14/799,799

(22) Filed: Jul. 15, 2015

Related U.S. Application Data
(60) Provisional application No. 62/026,101, filed on Jul. 18, 2014.

(51) Int. Cl. C23C 16/505

(52) U.S. Cl. CPC C23C 16/505

(57) ABSTRACT

Embodiments disclosed herein generally include methods for forming porous low k dielectric films. In one embodiment, a method of forming a porous low k dielectric film on a substrate using PECVD and in situ radical curing in a processing chamber is disclosed. The method includes introducing radicals into a processing region of the processing chamber, introducing a gas mixture into the processing region of the processing chamber, forming a plasma in the processing region and depositing the porous low k dielectric film on the substrate.

### CROSS-REFERENCE TO RELATED APPLICATIONS

This application claims priority to U.S. Provisional Patent Application Ser. No. 62/026,101, filed on Jul. 18, 2014, which herein is incorporated by reference.

### BACKGROUND

1. Field

Embodiments disclosed herein generally relate to methods for forming dielectric films, and more specifically to methods for forming porous low k dielectric films.

2. Description of the Related Art

The formation of low k dielectric films, such as porous low k dielectric films, is a critical task for developing the next generation of electronics devices. The crosstalk and RC delay problems in back-end-of-line have become a limiting factor to further improve device performance by dimension down-scaling. Therefore, reduction of effective k value of interlevel dielectrics (ILDs) is highly critical. Plasma enhanced chemical vapor deposition (PECVD) deposition is commonly used to form dielectric films. One example is to use PECVD to deposit porous carbon-doped oxide (CDO) films as ILD films. However, the development of highly porous CDO with a k value of less than 2.2 is challenging since the incorporation of high porosity will degrade further the thermomechanical and chemical strength.

Introduction of porosity is mainly realized by employing sacrificial porogen molecules. The dielectric film including the porogens is first deposited on a substrate in a PECVD chamber, and then the dielectric film may be exposed to hydrogen radicals in a separate processing chamber to remove the porogens. The porogen removal by hydrogen radicals is also known as radical curing. As the result of radical curing, porosity is created in the dielectric film and the k value is reduced. One drawback in this process is that hydrogen radicals used in the curing process has effective penetration depth of less than 1000 Angstroms. In order to deposit thicker films, multiple PECVD/curing processes are performed, leading to a reduced throughput.

Therefore, there is a need for methods for forming dielectric films, such as porous low k dielectric films.

### SUMMARY

Embodiments disclosed herein generally include methods for forming porous low k dielectric films. In one embodiment, a method of forming a porous low k dielectric film on a substrate using PECVD and in situ radical curing in a processing chamber is disclosed. The method includes introducing radicals into a processing region of the processing chamber, introducing a gas mixture into the processing region of the processing chamber, forming a plasma in the processing region and depositing the porous low k dielectric film on the substrate.

A method for forming porous low k dielectric films is disclosed. The method includes introducing radicals into a processing region of a processing chamber, introducing a fluid mixture into the processing region of the processing chamber, and forming a plasma in the processing region. The method further includes depositing and curing a porous low k dielectric film on a substrate disposed in the processing chamber.

In another embodiment, a method for forming porous low k dielectric films is disclosed. The method includes introducing a fluid mixture into a processing region of a processing chamber, forming a plasma in the processing region, depositing a porous low k dielectric film on a substrate disposed in the processing chamber, and curing the porous low k dielectric film with hydrogen radicals in the processing chamber during the deposition of the porous low k dielectric film.

In another embodiment, a method includes introducing radicals into a processing region of a processing chamber, the radicals are formed in a remote plasma source located outside of the processing chamber, introducing a fluid mixture into the processing region of the processing chamber, and forming a plasma in the processing region. The method further includes depositing and curing a porous low k dielectric film on a substrate disposed in the processing chamber.

### BRIEF DESCRIPTION OF THE DRAWINGS

So that the manner in which the above recited features of the disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a cross sectional view of an apparatus for forming dielectric films according to one embodiment described herein.

FIG. 2 illustrates a method for forming dielectric films according to embodiments described herein.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments disclosed herein generally include methods for forming porous low k dielectric films. In one embodiment, a method of forming a porous low k dielectric film on a substrate using PECVD and in situ radical curing in a processing chamber is disclosed. The method includes introducing radicals into a processing region of the processing chamber, introducing a gas mixture into the processing region of the processing chamber, forming a plasma in the processing region and depositing the porous low k dielectric film on the substrate.

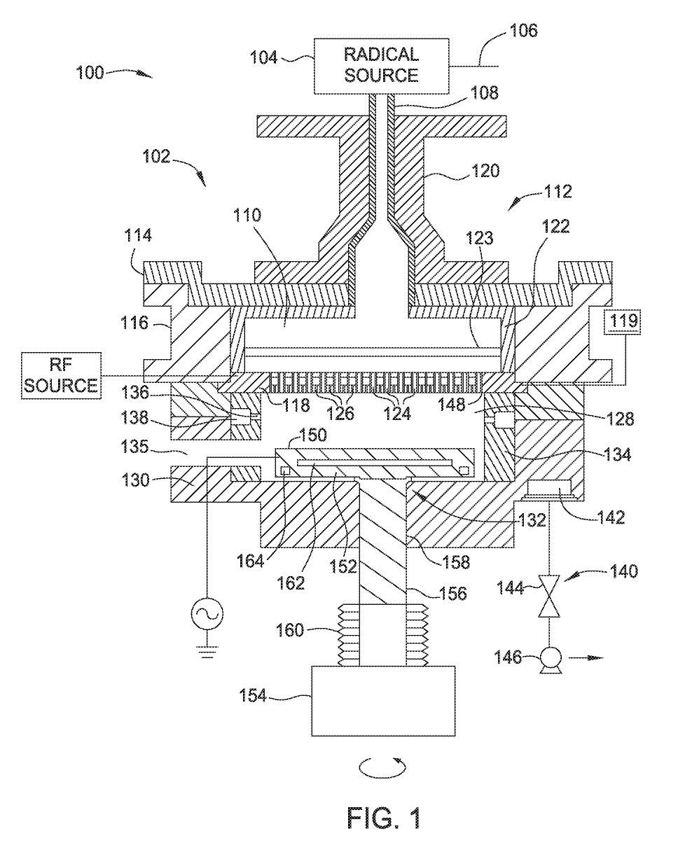

FIG. 1 is a cross sectional view of an apparatus 100 for forming dielectric films according to one embodiment described herein. In one embodiment, the apparatus 100 includes a processing chamber 102 and a radical source 104 coupled to the processing chamber 102. The radical source 104 may be any suitable source that is capable of generating radicals. The radical source 104 may be a remote plasma source, such as a radio frequency (RF) or very high radio frequency (VHRF) capacitively coupled plasma (CCP) source, an inductively coupled plasma (ICP) source, a microwave induced (MW) plasma source, an electron cyclotron resonance (ECR) chamber, or a high density plasma (HDP) chamber. Alternatively, the radical source 104 may be an ultraviolet (UV) source or the filament of a hot wire chemical vapor deposition (HW-CVD) chamber. The radical source 104 may include one or more gas inlets 106 and the radical source 104 may be coupled to the processing chamber 102 by a radical conduit 108. One or more process gases, which may be radical-forming gases, may enter the radical source 104 via the one or more gas inlets 106. The one or more process gases may comprise a hydrogen containing gas, such as hydrogen, H₂O, or ammonia. Radicals generated in the radical source 104, such as hydrogen radicals, travel into the processing chamber 102 through the radical conduit 108.

The radical conduit 108 is a part of a lid assembly 112, which also includes a radical cavity 110, a top plate 114, a lid rim 116, and a dual-zone showerhead 118. The radical conduit 108 may comprise a material that is substantially unreactive to radicals. For example, radical conduit 108 may comprise AlN, SiO₂, Y₂O₃, MgO, anodized Al₂O₃, sapphire, ceramics containing one or more of Al₂O₃, sapphire, AlN, Y₂O₃, MgO, or plastics. A representative example of a suitable SiO₂ material is quartz. Alternatively or additionally, radical conduit 108 may have a coating on the surface that contacts the radicals in operation. The coating may also comprise AlN, SiO₂, Y₂O₃, MgO, anodized Al₂O₃, sapphire, ceramics containing one or more of Al₂O₃, sapphire, AlN, Y₂O₃, MgO, or plastics. If a coating is used, the thickness of the coating may be between about 1 μm and about 1 mm. The coating may be applied using a spray coating process. The radical conduit 108 may be disposed within and supported by a radical conduit support member 120. The radical conduit support member 120 may be disposed on the top plate 114, which rests on the lid rim 116.

The radical cavity 110 is positioned below and coupled to the radical conduit 108, and the radicals generated in the radical source 104 travel to the radical cavity 110 through the radical conduit 108. The radical cavity 110 is defined by the top plate 114, the lid rim 116 and the dual-zone showerhead 118. Optionally, the radical cavity 110 may include a liner 122. The liner 122 may cover surfaces of the top plate 114 and the lid rim 116 that are within the radical cavity 110. The liner 122 may comprise a material that is substantially unreactive to radicals. For example, the liner 122 may comprise AlN, SiO₂, Y₂O₃, MgO, anodized Al₂O₃, sapphire, ceramics containing one or more of Al₂O₃, sapphire, AlN, Y₂O₃, MgO, or plastics. Alternatively or in addition to, the surfaces of the radical cavity 110 that are in contact with radicals may be composed of or coated with a material that is substantially unreactive to radicals. For example, the surfaces may be composed of or coated with AlN, SiO₂, Y₂O₃, MgO, anodized Al₂O₃, sapphire, ceramics containing one or more of Al₂O₃, sapphire, AlN, Y₂O₃, MgO, or plastics. If a coating is used, the thickness of the coating may be between about 1 μm and about 1 mm. By not consuming the generated radicals, the radical flux to a substrate disposed in the processing chamber 102 is increased.

An ion filter 123 may be disposed in the radical cavity 110 between the top plate 114 and the dual-zone showerhead 118. The ion filter 123 may be a perforated plate that is electrically grounded. If the radicals are generated within a plasma, the ions, electrons, and ultraviolet radiation generated in the plasma may be blocked by the ion filter 123 in order to direct only radicals to the dual-zone showerhead 118 and to prevent damage to the deposited film. Ion filter 123 can also control the number of radicals that pass through. Radicals then pass through a plurality of tubes 124 disposed in the dual-zone showerhead 118 to enter into a processing region 128. The dual-zone showerhead 118 further includes a plurality of openings 126 that are smaller in diameter than the plurality of tubes 124. The plurality of openings 126 are connected to an internal volume (not shown) that is not in fluid communication with the plurality of tubes 124. One or more fluid sources 119 may be coupled to the dual-zone showerhead 118 for introducing a fluid mixture into a processing region 128 of the processing chamber 102. The fluid mixture may include precursor, porogen, and/or carrier fluids. The fluid mixture may be a mixture of gases and liquids.

The processing chamber 102 may include the lid assembly 112, a chamber body 130 and a support assembly 132. The support assembly 132 may be at least partially disposed within the chamber body 130. The chamber body 130 may include a slit valve 135 to provide access to the interior of the processing chamber 102. The chamber body 130 may include a liner 134 that covers the interior surfaces of the chamber body 130. The liner 134 may include one or more apertures 136 and a pumping channel 138 formed therein that is in fluid communication with a vacuum system 140. The apertures 136 provide a flow path for gases into the pumping channel 138, which provides an egress for the gases within the processing chamber 102.

The vacuum system 140 may include a vacuum port 142, a valve 144 and a vacuum pump 146. The vacuum pump 146 is in fluid communication with the pumping channel 138 via the vacuum port 142. The apertures 136 allow the pumping channel 138 to be in fluid communication with the processing region 128 within the chamber body 130. The processing region 128 is defined by a lower surface 148 of the dual-zone showerhead 118 and an upper surface 150 of the support assembly 132, and the processing region 128 is surrounded by the liner 134.

The support assembly 132 may include a support member 152 to support a substrate (not shown) for processing within the chamber body 130. The substrate may be any standard wafer size, such as, for example, 300 mm. Alternatively, the substrate may be larger than 300 mm, such as 450 mm or larger. The support member 152 may comprise AlN or aluminum depending on operating temperature. The support member 152 may be configured to chuck the substrate and the support member 152 may be an electrostatic chuck or a vacuum chuck.

The support member 152 may be coupled to a lift mechanism 154 through a shaft 156 which extends through a centrally-located opening 158 formed in a bottom surface of the chamber body 130. The lift mechanism 154 may be flexibly sealed to the chamber body 130 by bellows 160 that prevents vacuum leakage from around the shaft 156. The lift mechanism 154 allows the support member 152 to be moved vertically within the chamber body 130 between a process position and a lower, transfer position. The transfer position is slightly below the opening of the slit valve 135. During operation, the spacing between the substrate and the dual-zone showerhead 118 may be minimized in order to maximize radical flux at the substrate surface. For example, the spacing may be between about 100 mm and about 5,000 mm. The lift mechanism 154 may be capable of rotating the shaft 156, which in turn rotates the support member 152, causing the substrate disposed on the support member 152 to be rotated during operation.

One or more heating elements 162 and a cooling channel 164 may be embedded in the support member 152. The heating elements 162 and cooling channel 164 may be used to control the temperature of the substrate during operation. The heating elements 162 may be any suitable heating elements, such as one or more resistive heating elements. The heating elements 162 may be connected to one or more power sources (not shown). The heating elements 162 may be controlled individually to have independent heating and/or cooling control on multi-zone heating or cooling. With the ability to have independent control on multi-zone heating and cooling, the substrate temperature profile can be enhanced at any giving process conditions. A coolant may flow through the channel 164 to cool the substrate. The support member 152 may further include gas passages extending to the upper surface 150 for flowing a cooling gas to the backside of the substrate.

An RF source may be coupled to either the dual-zone showerhead 118 or the support member 152. The RF source may be low frequency, high frequency, or very high frequency. In one embodiment, the dual-zone showerhead 118 is coupled to the RF source and the support member 152 is grounded, as shown in FIG. 1. In another embodiment, the dual-zone showerhead 118 is grounded and the support member 152 is coupled to the RF source. In either embodiment, a capacitively coupled plasma may be formed in the processing region 128 between the dual-zone showerhead 118 and the support member 152 during operation. The capacitively coupled plasma formed in the processing region 128 is in addition to the plasma formed in the radical source when the radical source is a remote plasma source. The support member 152 may be biased with a DC source to increase ion bombardment.

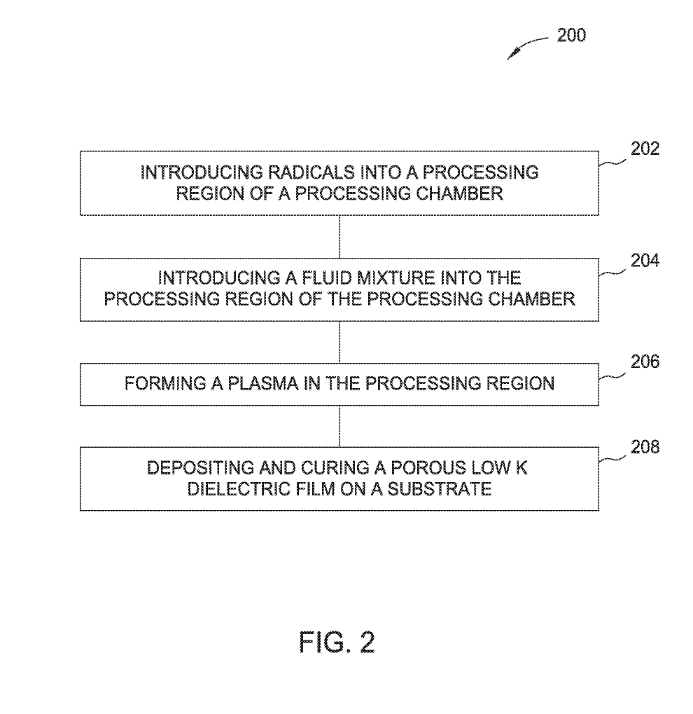

FIG. 2 illustrates a method 200 for forming porous low k dielectric films. At block 202, radicals are introduced into a processing region of a processing chamber. The processing chamber may be the processing chamber 102 shown in FIG. 1 and the processing region may be the processing region 128 shown in FIG. 1. The processing chamber may be a PECVD chamber with a radical source coupled thereto. Radicals may be formed in the radical source, such as the radical source 104 shown in FIG. 1. In one embodiment, the radicals are formed in a remote plasma source. One or more gases may be flowed into the remote plasma source. The one or more gases may include a hydrogen containing gas, such as hydrogen, H₂O, ammonia or other suitable hydrogen containing gas. The one or more gases may also include an inert carrier gas, such as argon. In one embodiment, hydrogen gas is introduced into the remote plasma source at a flow rate up to about 10,000 sccm, and argon gas is introduced into the remote plasma source at a flow rate ranging from about 0 sccm to about 10,000 sccm. Hydrogen radicals may be generated in the remote plasma source using an RF power, and the RF power may be between about 10 W to about 20,000 W. The radicals formed in the remote plasma source then travel to the processing region through the dual-zone showerhead.

At block 204, a fluid mixture is introduced into the processing region of the processing chamber. The fluid mixture may be introduced from the one or more fluid sources 119 as shown in FIG. 1. The fluid mixture may include precursor fluid such as a silicon containing fluid. In one embodiment, the precursor fluid is a silicon and carbon containing fluid. Examples of the precursor fluid include (dimethylsilyl)(trimethylsilyl)methane ((Me)₃SiCH₂SiH(Me)₂), hexamethyldisilane ((Me)₃SiSi(Me)₃), tetramethoxysilane ((MeO)₄Si), trimethylsilane ((Me)₃SiH), tetramethylsilane ((Me)₄Si), tetraethoxysilane ((EtO)₄Si), (dimethylamino)dimethylsilane ((Me₂N)SiHMe₂), tetrakis-(trimethylsilyl)silane ((Me₃Si)₄Si), dimethyldiethoxysilane ((EtO)₂Si(Me)₂), diethoxymethylsilane ((EtO)₂Si(Me)), dimethyldimethoxysilane ((MeO)₂Si(Me)₂), methyltrimethoxysilane ((MeO)₃Si(Me)), dimethoxytetramethyl-disiloxane (((Me)₂SKOMe))₂O), bis(dimethylamino)methylsilane ((Me₂N)₂CH₃SiH), tris(dimethylamino)silane ((Me₂N)₃SiH), and combinations thereof.

The fluid mixture may also include a porogen, such as 1-isopropyl-4-methyl-1,3-cyclohexadiene or bicyclo(2.2.1)-hepta-2,5-diene. Additionally, the fluid mixture may include an oxygen containing gas and an inert carrier gas such as helium or argon. In one embodiment, the fluid mixture includes diethoxymethylsilane at a flow rate of about 100 milligram per minute (mgm) to about 4000 mgm, 1-isopropyl-4-methyl-1,3-cyclohexadiene or bicyclo(2.2.1)-hepta-2,5-diene at a flow rate of about 100 mgm to about 4000 mgm, oxygen gas at a flow rate of about 10 sccm to about 1000 sccm, helium gas at a flow rate of about 0 sccm to about 10,000 sccm and argon gas at a flow rate of about 0 sccm to about 10,000 sccm.

The fluid mixture and the radicals are not mixed in the dual-zone showerhead since the dual-zone showerhead includes two zones that are not in fluid communication with each other. Both fluid mixture and the radicals are introduced into the processing region via the dual-zone showerhead. With the radicals and fluid mixture in the processing region, a plasma is formed in the processing region, at block 206. The plasma may be formed by an RF power having a power density ranging from about 0.01 W/cm² to about 100 W/cm². Next, at block 208, a porous low k dielectric film is deposited on a substrate disposed in the processing chamber, and the porous low k dielectric film is cured as the porous low k dielectric film is deposited. The porous low k dielectric film may be a silicon and carbon containing film, such as SiC, SiOC, SiOCN, or any suitable dielectric films. During the deposition and curing, the processing chamber may have a pressure of about 0.001 Torr to about 10 Torr and the substrate has a temperature of about 50 degrees Celsius to about 400 degrees Celsius. In situ curing using radicals, such as hydrogen radicals during the PECVD process further reduces the k value while improving film homogeneousity. In addition, PECVD and curing processes are performed in the same processing chamber at the same time, thus throughput is increased.

In an alternative embodiment, a cyclic PECVD/curing process may be performed in the processing chamber to form a porous low k dielectric film. A dielectric film including porogens may be first deposited on a substrate disposed in the processing chamber. The dielectric film may have a thickness that is less than the effective penetration depth of hydrogen radicals. Then the hydrogen radicals are used to remove the porogens. Then the PECVD/curing process is repeated until a predetermined thickness of the porous low k dielectric film is reached.

In summary, methods for forming porous low k dielectric films are disclosed. The porous low k dielectric film may be deposited using PECVD and cured with radicals at the same time in the same processing chamber. By performing in situ radical curing during PECVD process, throughput is increased, k value is decreased and porosity is improved.

While the foregoing is directed to embodiments, other and further embodiments may be devised without departing from the basic scope thereof, and the scope thereof is determined by the claims that follow.

1. A method for forming porous low k dielectric films, comprising:
introducing radicals into a processing region of a processing chamber;
introducing a fluid mixture into the processing region of the processing chamber;
forming a plasma in the processing region; and
depositing and curing a porous low k dielectric film on a substrate disposed in the processing chamber.

2. The method of claim 1, wherein the radicals include hydrogen radicals.

3. The method of claim 2, wherein the radicals are generated in a remote plasma source disposed outside of the processing chamber.

4. The method of claim 3, wherein the radicals are generated in the remote plasma source using an RF power, wherein the RF power is between about 10 W to about 20,000 W.

5. The method of claim 4, further comprising flowing a hydrogen containing gas into the remote plasma source and the flow rate of the hydrogen containing gas is less than about 10,000 sccm.

6. The method of claim 1, wherein the fluid mixture includes a silicon and carbon containing fluid.

7. The method of claim 6, wherein the fluid mixture further includes a porogen.

8. The method of claim 7, wherein the silicon and carbon containing fluid and the porogen each has a flow rate of about 100 mgm to about 4000 mgm.

9. The method of claim 7, wherein the fluid mixture further includes an oxygen containing gas.

10. The method of claim 9, wherein the oxygen containing gas has a flow rate of about 10 sccm to about 1000 sccm.

11. The method of claim 1, wherein the plasma is formed using an RF power having a power density ranging from about 0.014 W/cm² to about 1.4 W/cm².

12. The method of claim 1, wherein the porous low k dielectric film is a silicon and carbon containing film.

13. A method for forming porous low k dielectric films, comprising:
introducing a fluid mixture into a processing region of a processing chamber;
forming a plasma in the processing region;
depositing a porous low k dielectric film on a substrate disposed in the processing chamber; and
curing the porous low k dielectric film with hydrogen radicals in the processing chamber during the deposition of the porous low k dielectric film.

14. The method of claim 13, wherein the fluid mixture includes a silicon and carbon containing fluid.

15. The method of claim 14, wherein the fluid mixture further includes a porogen.

16. The method of claim 15, wherein the silicon and carbon containing fluid and the porogen each has a flow rate of about 100 mgm to about 4000 mgm.

17. The method of claim 15, wherein the fluid mixture further includes an oxygen containing gas.

18. The method of claim 17, wherein the oxygen containing gas has a flow rate of about 10 sccm to about 1000 sccm.

19. A method for forming porous low k dielectric films, comprising:
introducing radicals into a processing region of a processing chamber, wherein the radicals are formed in a remote plasma source located outside of the processing chamber;
introducing a fluid mixture into the processing region of the processing chamber;
forming a plasma in the processing region; and
depositing and curing a porous low k dielectric film on a substrate disposed in the processing chamber.

20. The method of claim 19, wherein the radicals are generated in the remote plasma source using an RF power, wherein the RF power is between about 10 W to about 20,000 W.
